(19) United States
(12) Patent Application Publication
(10) Pub. No.: US 2010/0329616 A1
(43) Pub. Date: Dec. 30, 2010

(54) PHOTOSENSITIVE RESIN COMPOSITION, METHOD FOR CONTROL OF REFRACTIVE INDEX, AND OPTICAL WAVEGUIDE AND OPTICAL COMPONENT USING THE SAME

(76) Inventors: Ning-Juan Chen, Tokyo (JP); Shinji Ando, Tokyo (JP); Kaichiro Nakano, Tokyo (JP); Katsumi Maeda, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 12/440,007

(22) PCT Filed: Aug. 29, 2007
(86) PCT No.: PCT/JP2007/067241

§ 371 Date: Aug. 30, 2010

(30) Foreign Application Priority Data
Sep. 4, 2006 (JP) 2006-238847

(51) Int. Cl. G02B 6/02; G03F 7/20; G03F 7/004

(52) U.S. Cl. 385/123; 430/330; 430/270.1

(57) ABSTRACT

Provided are: a resin composition for the formation of an optical waveguide, which shows low transmission loss and high heat stability and enables to form a waveguide pattern at high shape accuracy and at low cost; an optical waveguide; a method of forming an optical waveguide; and an optical element using the method. A photosensitive resin composition is used, which includes a polyamic acid represented by a general formula (I) or a polyamic acid ester (A), a compound (B) having an epoxy group, and a compound (C) which generates an acid by being exposed to light.

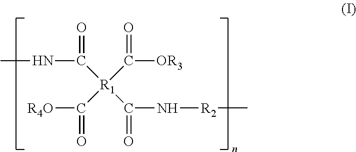

### TECHNICAL FIELD

This invention relates to an optical waveguide to be utilized in, for example, an optical element, optical interconnection, optical wiring board, or optical-electrical mixed circuit board for use in, for example, an optical communication field or optical information processing field, a photosensitive resin composition for use in production of the optical waveguide, a method of forming the optical waveguide, and an optical component such as an optical element using the optical waveguide.

### BACKGROUND ART

The Internet and digital household electrical appliances have rapidly become widespread in recent years. In association with the widespread, a communication system or computer has been requested to process information at an enlarged capacity and an increased speed, and investigations have been conducted on high-speed transmission of large-capacity data with a high-frequency signal.

However, when one attempts to transmit large-capacity signals with high-frequency, large transmission loss is inevitable in conventional electric wiring. In view of the foregoing, active investigations have been conducted on a transmission system based on light, and the use of the system in, for example, wiring between computers, wiring in an apparatus, or wiring for inboard communication has become imminent. Of the elements for realizing the transmission system based on light, an optical waveguide is requested to show high performance and to be available at a low cost because the optical waveguide can be a basic component in, for example, an optical element, optical interconnection, optical wiring board, or optical-electrical mixed circuit board.

Optical waveguides are each optical wiring formed on a substrate, and are classified into a glass waveguide and a polymer waveguide. The application of a waveguide to an element for an optical interconnection, an optical wiring board, or the like requires the formation of the waveguide at a cost comparable to that in the case where the waveguide is formed by a conventional electric wiring technique. However, the glass waveguide, which has already become commercial, is composed of a clad layer of silica glass and a core layer obtained by adding germanium to silica glass. All those layers are each formed by a vapor phase growth method, and each undergo a heating process at 1,000° C. or higher by a flame hydrolysis deposition method.

That is, a production cost for the glass waveguide is high, and the production of the glass waveguide requires a high-temperature heating process. Owing to the reasons including those described above, it may be difficult to match the glass waveguide with a printed wiring board or the like in a production process. Further, the glass waveguide involves a large number of problems including the following problem to be solved in terms of its production process and cost before the production of the glass waveguide on an industrial scale becomes feasible: it is difficult to produce a large-area glass waveguide.

On the other hand, a polymer material may be superior to a conventional optical material such as quartz glass in, for example, cost, processability, and ease of molecular design. That is, a process for the formation of a waveguide using an organic material such as a polymer can be performed at low temperatures because a desired film can be formed by spin coating. In addition, the film can be easily formed on any one of the various substrates such as a semiconductor substrate, a copper-polyimide wiring board, and a polymer substrate, so the polymer material has the potential to improve the performance of a waveguide and to increase the number of kinds of available waveguides as well as to achieve low-cost, high-yield production of a waveguide. In actuality, investigations have been heretofore conducted on waveguides each using a polymer material such as polymethyl methacrylate (PMMA), an epoxy resin, a polysiloxane derivative, or fluorinated polyimide.

For example, Japanese Patent Application Laid-Open No. Hei 10-170738 (Patent Document 1) and Japanese Patent Application Laid-Open No. Hei 11-337752 (Patent Document 2) disclose a polymer waveguide using an epoxy compound. In addition, Japanese Patent Application Laid-Open No. Hei 9-124793 (Patent Document 3) discloses a waveguide using a polysiloxane derivative.

In general, however, it has been pointed out that a waveguide composed of a resin composition as an organic compound involves such problems as described below: the waveguide has low heat resistance, and shows large transmission loss in a wavelength region of 600 to 1,600 nm used in optical communication. To solve those problems, investigations have been conducted on, for example, the following approaches: the transmission loss is reduced by chemical modification such as the deuteration or fluorination of a polymer, and a polyimide derivative having heat resistance is used. For example, Japanese Patent Application Laid-Open No. 2005-29652 (Patent Document 4) describes a waveguide using a polyether ketone derivative. However, deuterated PMMA and fluorinated polyimide involve the following drawbacks: deuterated PMMA has low heat resistance; although fluorinated polyimide is excellent in heat resistance, the formation of a waveguide pattern from fluorinated polyimide requires a dry etching step as in the case of a quartz waveguide, so a production cost for the waveguide pattern becomes high.

Meanwhile, Japanese Patent Application Laid-Open No. 2002-277662 (Patent Document 5), which does not relate to an optical waveguide, discloses two kinds of core materials for optical waveguide couplers: a core material made from a photosensitive polyamic acid and a core material made from an epoxy-, acrylic, or silicone-based oligomer or monomer.

### DISCLOSURE OF THE INVENTION

### Problem to be Solved by the Invention

Therefore, in formation of an optical waveguide using a photosensitive resin, there are demanded a photosensitive resin composition for the formation of an optical waveguide having low transmission loss, and enables the production of a waveguide pattern with high shape accuracy and at low cost, an optical waveguide, and a method of forming an optical waveguide pattern.

In view of the foregoing, a technical object of this invention is to provide a photosensitive resin composition for the formation of an optical waveguide having low transmission loss, and enables the production of a waveguide pattern with high shape accuracy and at low cost, an optical waveguide, and a method of forming an optical waveguide pattern.

### Means to Solve the Problem

The inventors of this invention have conducted investigations with a view to solving the above problems. As a result, the inventors have found that, when a resin having a polyimide structure is used as a main component in a resin composition for forming one or both of the core layer and clad layer of an optical waveguide, each layer can be provided with a suitable refractive index, the waveguide shows low transmission loss, and the pattern shape of the waveguide can be formed with high accuracy. Thus, this invention has been completed based on this finding.

That is, a photosensitive resin composition according to a first aspect of this invention comprises: a polyamic acid (A) represented by a general formula (I); a compound (B) having an epoxy group; and a compound (C) which generates an acid by being exposed to light:

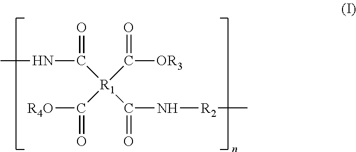

where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

Further, a method of controlling a refractive index according to a second aspect of this invention comprises: irradiating a photosensitive resin composition with an active light beam; and subsequently heating the photosensitive resin composition to cause a difference in refractive index to arise between a portion exposed to the active light beam and a portion unexposed to the active light beam, wherein the photosensitive resin composition contains a polyamic acid (A) represented by a general formula (I) shown below, a compound (B) having an epoxy group, and a compound (C) which generates an acid by being exposed to light:

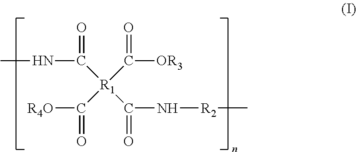

where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

Here, in the second aspect of this invention, it is preferable that the difference in refractive index be arisen between an exposed portion and an unexposed portion by irradiating the active light beam and subsequently heating.

An optical waveguide according to a third aspect of this invention, wherein a portion having a higher refractive index and a portion having a lower refractive index, which are obtained by the method of controlling a refractive index, are used as a core and a clad, respectively.

An optical waveguide according to a fourth aspect of this invention, comprises: a core layer; and a clad layer formed by lamination on the core layer, wherein a photosensitive resin composition is used in one or both of the core layer and the clad layer, and the photosensitive resin composition contains a polyamic acid (A) represented by a general formula (I) shown below, a compound (B) having an epoxy group, and a compound (C) which generates an acid by being exposed to light:

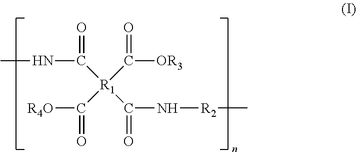

where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

A method of forming an optical waveguide pattern according to a fifth aspect of this invention comprises at least the steps of: forming a first clad layer on a substrate; applying a photosensitive resin composition onto the first clad layer; prebaking the resultant; irradiating one of a region to serve as a core and a region to serve as a portion except the core in the photosensitive resin composition layer with an active light beam through a mask; and forming a second clad layer on the core and the first clad layer thus formed, wherein the photosensitive resin composition contains a polyamic acid (A) represented by a general formula (I) shown below, a compound (B) having an epoxy group, and a compound (C) which generates an acid by being exposed to light:

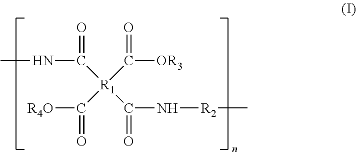

where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

An optical component according to a sixth aspect of this invention comprises an optical element or device, wherein the optical component uses an optical waveguide formed by the method of forming an optical waveguide pattern.

### EFFECT OF THE INVENTION

The photosensitive resin composition for the formation of an optical waveguide of this invention enables the formation of a waveguide pattern with high accuracy without requiring a developing process involving the use of a solvent. Further, the formed optical waveguide shows an excellent transmission characteristic, i.e., low propagation loss, and has high heat stability originating from a polyimide skeleton. Accordingly, the optical waveguide can be suitably used as an optical waveguide that can find applications in optical elements and devices.

### BRIEF DESCRIPTION OF THE DRAWINGS

FIG. 1 shows schematic sectional views (a) to (f) showing an example of production steps for a polymer waveguide based on a photosensitive resin composition according to this invention.

FIG. 2 shows schematic sectional views (a) to (d) showing the production steps for the polymer waveguide based on the photosensitive resin composition according to this invention.

FIG. 3 shows schematic sectional views (a) to (f) showing another example of the production steps for the polymer waveguide based on the photosensitive resin composition according to this invention.

FIG. 4 shows schematic sectional views (a) to (d) showing still another example of the production steps for the polymer waveguide based on the photosensitive resin composition according to this invention.

### DESCRIPTION OF REFERENCE NUMERALS

1 substrate
2a, 2b lower clad layer
3a, 3b, 3c ultraviolet ray
4a, 4b, 4c core layer formed of photosensitive resin composition for optical waveguide of this invention
5a, 5b photomask
6a, 6b core portion formed
7a, 7b, 7c, 7d upper clad layer formed of photosensitive resin composition for optical waveguide of this invention

### BEST MODE FOR EMBODYING THE INVENTION

Hereinafter, a photosensitive resin composition for the formation of an optical waveguide of this invention and a method of forming an optical waveguide of this invention will be specifically described.

(Resin Composition for Formation of Optical Waveguide)

The resin composition for the formation of an optical waveguide

(hereinafter referred to as “resin composition”) of this invention is obtained by incorporating at least a polyamic acid or polyamic acid ester (A) represented by a general formula (I) shown below, a compound (B) having an epoxy group, and a compound (C) which generates an acid by being exposed to light.

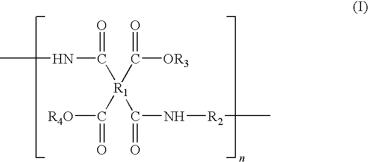

A repeating structural unit represented by the general formula (I) of this invention is basically a polyamic acid structure or polyamic acid ester structure obtained from a tetracarboxylic dianhydride and a diamine. That is, R1 represents a residue obtained by removing the carboxyl groups of a tetracarboxylic acid, preferably a group containing an aromatic ring, or more suitably a group containing an aromatic ring and having 6 to 40 carbon atoms. The group containing an aromatic ring is suitably a tetravalent organic group having one aromatic ring, or a tetravalent organic group having a chemical structure in which two or more aromatic rings are bonded to each other through any one of a single bond, an ether bond, a methylene bond, an ethylene bond, a 2,2-hexafluoropropylidene bond, a sulfone bond, a sulfoxide bond, a thioether bond, and a carbonyl bond.

Examples of the teteracarboxylic dianhydride include tetravalent organic groups where R1 represents benzene, alkyl benzene, or perfluoroalkylbenzene, such as pyromellitic dianhydride, (trifluoromethyl)pyromellitic dianhydride, and di(trifluoromethyl)pyromellitic dianhydride. In addition, examples thereof include a tetravalent organic group where R1 represents an aromatic hydrocarbon having two or more benzene rings, an ether thereof, a ketone thereof, or a substituent thereof with one or more perfluoroalkyl groups, such as bis{3,5-di(trifluoromethyl)phenoxy}pyromellitic dianhydride, 2,3,3′,4′-biphenyltetracarboxylic dianhydride, 3,3′,4,4′-tetracarboxydiphenylether dianhydride, 2,3′,3,4′-tetracarboxydiphenylether dianhydride, 3,3′,4,4′-benzophenone tetracarboxylic dianhydride, 2,3,6,7-tetracarboxynaphthalene dianhydride, 1,4,5,7-tetracarboxynaphthalene dianhydride, 1,4,5,6-tetracarboxynaphthalene dianhydride, 3,3′,4,4′-tetracarboxydiphenylmethane dianhydride, 2,2-bis(3,4-diacarboxyphenyl)propane dianhydride, 2,2-bis(3,4-dicarboxyphenyl)hexafluoropropane dianhydride, 5,5′-bis(trifluoromethyl)-3,3′,4,4′-tetracarboxybiphenyl dianhydride, 2,2′,5,5′-tetrakis(trifluoromethyl)-3,3′,4,4′-tetracarboxybiphenyl dianhydride, 5,5′-bis(trifluoromethyl)-3,3′,4,4′-tetracarboxydiphenylether dianhydride, 5,5′-bis(trifluoromethyl)-3,3′,4,4′-tetracarboxybenzophenone dianhydride, bis{(trifluoromethyl)dicarboxyphenoxy}benzene dianhydride, bis{(trifluoromethyl)dicarboxyphenoxy}(trifluoromethyl)benzene dianhydride, bis(dicarboxyphenoxy)(trifluoromethyl)benzene dianhydride, bis(dicarboxyphenoxy)bis(trifluoromethyl)benzene dianhydride, bis(dicarboxyphenoxy)tetrakis(trifluoromethyl)benzene dianhydride, 3,4,9,10-tetracarboxyperylene dianhydride, 2,2-bis{4-(3,4-dicarboxyphenoxy)phenyl}propane dianhydride, butanetetracarboxylic dianhydride, cyclopentane tetracarboxylic dianhydride, 2,2-bis{4-(3,4-dicarboxyphenoxy)phenyl}hexafluoropropane dianhydride, bis{(trifluoromethyl)dicarboxyphenoxy}biphenyl dianhydride, bis{(trifluoromethyl)dicarboxyphenoxy}bis(trifluoromethyl)biphenyl dianhydride, bis{(trifluoromethyl)dicarboxyphenoxy}diphenylether dianhydride, bis(dicarboxyphenoxy)bis(trifluoromethyl)biphenyl dianhydride, bis(3,4-dicarboxyphenyl)dimethyl silane dianhydride, 1,3-bis(3,4-dicarboxyphenyl)tetramethyl disiloxane dianhydride, difluoropyromellitic dianhydride, 1,4-bis(3,4-dicarboxytrifluorophenoxy)tetrafluorobenzene dianhydride, 1,4-bis(3,4-dicarboxytrifluorophenoxy)octafluorobiphenyl dianhydride, and 4,4′-hexafluoroisoproylidene diphthalic dianhydride. In addition, there may be used as a raw material a dianhydride having a structure in which a part or all of carbons contained in the aromatic ring of those dianhydrides are substituted with a saturated carbon which is free of aromaticity by hydrogenation treatment or the like. Examples of the dianhydride are not limited thereto.

It should be noted that R5 are preferably free of the tetravalent groups of a bisalkylbenzene and a bisperfluoroalkylbenzene.

In addition, R2 in the repeating unit represented by the general formula (I) preferably represents a residue obtained by removing the amino groups of a diamine compound capable of reacting with a tetracarboxylic acid or a derivative of the acid to form a polyimide precursor. Of such residues, a divalent organic functional group having one benzene ring is preferable, a group that forms a phenylene group, fluorophenylene group, fluoroalkylphenylene group, or alkylphenylene group is also preferable, and a divalent organic functional group having two or more benzene rings is also preferable. Further, a divalent organic functional group containing Si is also preferable.

A diamine compound that forms a phenylene group having one benzene ring is, for example, m-phenylenediamine.

In addition, examples of the diamine compounds each forming a fluorophenylene group or a fluoroalkylphenylene group include 1,3-diaminotetrafluorobenzene, 1,4-diaminotetrafluorobenzene, 2,5-diaminobenzotrifluoride, bis(trifluoromethyl)phenylene diamine, diaminotetra(trifluoromethyl)benzene, and diamino(pentafluoroethyl)benzene. 1,3-diaminotetrafluorobenzene, 1,4-diaminotetrafluorobenzene, 2,5-diaminobenzotrifluoride, and bis(trifluoromethyl)phenylene diamine other than perfluorophenylene are preferred.

In addition, examples of the diamine compound forming an alkylphenylene group include 2,4-diaminotoluene, 2,4-diaminoxylene, 2,4-diaminodurene, p-phenylene diamine, 2,5-diaminotoluene, and 2,3,5,6-tetramethyl-p-phenylene diamine.

In addition, examples of the diamine compounds each forming a divalent organic functional group having two or more benzene rings include benzidine, 2,2-dimethyl benzidine, 3,3′-dimethyl benzidine, 3,3′-dimethoxy benzidine, 2,2-dimethoxy benzidine, 3,3′,5,5′-tetramethyl benzidine, 3,3′-diacetyl benzidine, 2,2′-bis(trifluoromethyl)-4,4′-diaminobiphenyl, octafluorobenzidine, 3,3′-bis(trifluoromethyl)-4,4′-diaminobiphenyl, 4,4′-diaminodiphenyl ether, 4,4′-diaminodiphenyl methane, 2,2-bis(p-aminophenyl)propane, 3,3′-dimethyl-4,4′-diaminodiphenyl ether, 3,3′-dimethyl-4,4′-diaminodiphenyl methane, 2,2′-bis(trifluoromethyl)-4,4′-diaminodiphenyl ether, 3,3′-bis(trifluoromethyl)-4,4′-diaminodiphenyl ether, 3,3′-bis(trifluoromethyl)-4,4′-diaminobenzophenone, 4,4″-diamino-p-terphenyl, 1,4-bis(p-aminophenyl)benzene, p-bis(4-amino-2-trifluoromethylphenoxy)benzene, 4,4′″-diamino-p-quaterphenyl, 4,4′-bis(p-aminophenoxy)biphenyl, 2,2-bis{4-(p-aminophenoxy)phenyl}propane, 4,4′-bis(3-aminophenoxyphenyl)diphenyl sulfone, 2,2-bis{4-(4-aminophenoxy)phenyl}hexafluoropropane, 2,2-bis{4-(3-aminophenoxy)phenyl}hexafluoropropane, 2,2-bis{4-(2-aminophenoxy)phenyl}hexafluoropropane, 2,2-bis{4-(4-aminophenoxy)-3,5-dimethylphenyl}hexafluoropropane, 2,2-bis{4-(4-aminophenoxy)-3,5-ditrifluoromethylphenyl}hexafluoropropane, 4,4′-bis(4-amino-2-trifluoromethylphenoxy)biphenyl, 4,4′-bis(4-amino-3-trifluoromethylphenoxy)biphenyl, 2,2-bis{4-(4-amino-3-trifluoromethylphenoxy)phenyl}hexafluoropropane, bis{(trifluoromethyl)aminophenoxy}biphenyl, bis[{(trifluoromethyl)aminophenoxy}phenyl]hexafluoropropane, diaminoanthraquinone, 1,5-diaminonaphthalene, 2,6-diaminonaphthalene, bis[{2-(aminophenoxy)phenyl}hexafluoroisopropyl]benzene, and bis(2,3,5,6)-tetrafluoro-4-aminophenyl ether.

Further, examples of the organic silicon diamine compounds each forming a divalent organic functional group containing Si include 1,3-bis(3-aminopropyl)tetramethyl disiloxane, 1,4-bis(3-aminopropyldimethyl silyl)benzene, bis(4-aminophenyl)diethyl silane, and 4,4′-bis(tetrafluoroaminophenoxy)octafluorobiphenyl.

In addition, a diamine compound having a structure obtained by replacing part or all of carbons in an aromatic ring of each of those diamine compounds with saturated carbons each of which is free of aromaticity by an approach such as a hydrogenation treatment can also be used as a raw material. However, the raw material is not limited to the foregoing.

In the repeating structural unit represented by the general formula (I), R3 and R4 represent a hydrogen atom and a substituent which is degraded by acid, respectively. Examples of the groups represented by R3 and R4 include, but are of course not limited to, a t-butyl group, a t-butoxycarbonyl group, a t-butoxycarbonylmethyl group, a tetrahydropyranyl group, a tetrahydrofuranyl group, an ethoxyethyl group, a methoxyethyl group, an ethoxymethyl group, a trimethylsilyl group, and a trimethylsilyl ether group.

In addition, the weight average molecular weight (Mw) of the polymer to be obtained is preferably 1,000 or more and more preferably 4,000 or more, and preferably 1,000,000 or less and more preferably 500,000 or less.

In addition, a photo-acid-generating agent used in the photosensitive resin composition of this invention is desirably a photo-acid-generating agent which generates an acid by being irradiated with an active light beam. The photo-acid-generating agent is not particularly limited as long as the following conditions are satisfied: a mixture of the photo-acid-generating agent with the polymer and the like in this invention sufficiently dissolves in an organic solvent, and a uniform coating film can be formed of the solution by a film formation method such as spin coating. In addition, one kind of a photo-acid-generating agent may be used alone, or two or more kinds of photo-acid-generating agents may be used as a mixture.

Examples of the usable photo-acid-generating agent include, but are of course not limited to, triaryl sulfonium salt derivatives, diaryliodonium salt derivatives, dialkylphenacyl sulfonium salt derivatives, nitrobenzyl sulfonate derivatives, a sulfonate of N-hydroxynaphthalimide, sulfonate derivatives of N-hydroxysuccinimide.

The content of the photo-acid-generating agent is preferably 0.1 mass % or more, or more preferably 0.5 mass % or more with respect to the total sum of the polymer, the epoxy compound, and the photo-acid-generating agent, or, if the photosensitive resin composition further contains an oxetane compound, the total sum of the polymer, the epoxy compound, the photo-acid-generating agent, and the oxetane compound from the following viewpoints: the photosensitive resin composition realizes sufficient sensitivity, and enables good pattern formation. Meanwhile, the content is preferably 15 mass % or less, or more preferably 7 mass % or less from the following viewpoints: the formation of a uniform coating film is realized, and none of the characteristics of a waveguide is impaired.

The photosensitive resin composition of this invention includes an epoxy compound in addition to the polymer and photo-acid-generating agent. Examples of the epoxy compound, but are of course not limited to, include bisphenol A diglycidylether, hydrogenated bisphenol A diglycidylether, ethyleneglycol diglycidylether, diethyleneglycol diglycidylether, propyleneglycol diglycidylether, tripropyleneglycol diglycidylether, neopentylglycol diglycidylether, 1-6-hexanediol diglycidylether, glycerin diglycidylether, trimethylopropane triglycidylether, 1,2-cyclohexane carboxylic diglycidyl ester, 3,4-epoxycyclohexylmethyl 3,4-epoxycyclohexane carboxylate, trisepoxypropyl isocyanurate, 2-epoxyethylbicyclo[2,2,1]heptylglycidyl ether, ethylene glycol bis(2-epoxyethylbicyclo[2,2,1]heptyl)ether, and bis(2-epoxyethylbicyclo[2,2,1]heptyl)ether.

The content ratio of the epoxy compound is generally 0.5 to 80 mass % and preferably 1 to 70 mass % with respect to all constituent components including the epoxy compound itself. In addition, the epoxy compound may be used alone or used in combination of two or more kinds.

In addition, the photosensitive resin composition of this invention may include an oxetane compound in addition to the polymer, photosensitive agent, and epoxy compound. Examples of the oxetane compound include, but are of course not limited to, 3-ethyl-3-hydroxymethyl oxetane, 1,4-bis{[(3-ethyl-3-oxetanyl)methoxy]methyl}benzene, 3-ethyl-3-(phenoxymethyl)oxetane, di[1-ethyl(3-oxetanyl)]methyl ether, 3-ethyl-3-(2-ethylhexyloxymethyl)oxetane, and 3-ethyl-3{[3-(triethoxysilyl)propoxy]methyl}oxetane.

In the case where the oxetane compound is added, the content ratio thereof is generally 0.5 to 80 mass % and more preferably 1 to 70 mass % with respect to all constituent components including the oxetane compound itself. In addition, the oxetane compound may be used alone or used in combination of two or more kinds.

In addition, various inorganic fine particles as well as the polymer, the photo-acid-generating agent, the epoxy compound, and the oxetane compound described above may be added as an additive to the resin composition including photosensitive resin composition of this invention to such an extent that the characteristics of an optical waveguide made from the composition are not impaired. Examples of such additive include alumina, silica, glass fibers, glass beads, silicone, and metal oxides such as titanium oxide. The addition of any such additive can: improve the cracking resistance and heat resistance of the optical waveguide; reduce the elastic modulus of the waveguide; or alleviate the warping of the waveguide.

Further, the resin composition including photosensitive resin composition of this invention can be prepared by adding a component such as an adhesiveness improver, a leveling agent, an application property improver, a wettability improver, a surfactant, a photosensitizer, a dehydrating agent, a polymerization inhibitor, a polymerization initiator, a UV absorber, a plasticizer, an antioxidant, or an antistatic agent as required to such an extent that an effect of this invention is not impaired.

It should be noted that a proper solvent is used as required upon preparation of the resin composition including photosensitive resin composition described above. The solvent is not particularly limited as long as the solvent is an organic solvent or the like satisfying the following conditions: the photosensitive resin composition can sufficiently dissolve in the solvent, and the solution can be uniformly applied by a method such as a spin coating method. Specifically, γ-butyrolactone, N,N-dimethylacetoamide, propyleneglycol monomethylether acetate, propyleneglycol monoethylether acetate, ethyl lactate, 2-heptanone, 2-methoxybutyl acetate, 2-ethoxyethyl acetate, methyl pyruvate, ethyl pyruvate, methyl 3-methoxypropionate, ethyl 3-methoxypropionate, N-methyl-2-pyrrolidone, cyclohexanone, cyclopentanone, methylisobutyl ketone, ethyleneglycol monomethylether, ethyleneglycol monomethylether acetate, ethyleneglycol monoethylether, ethyleneglycol monoisopropylether, diethyleneglycol monomethylether, diethyleneglycol dimethylether, or the like may be used. Those compounds may be used alone or used in combination of two or more kinds.

(Method of Forming Waveguide Pattern)

The production of a polymer optical waveguide according to this invention will be described. The polymer optical waveguide is composed of a core having a higher refractive index and a clad having a lower refractive index, and is formed so as to be of such a shape that the core is surrounded with the clad. The polymer optical waveguide is obtained by a method of forming a waveguide pattern including at least the steps of:

(1) forming a lower clad layer on an appropriate substrate;
(2) applying the photosensitive resin composition of this invention onto the above lower clad layer;
(3) subjecting the resultant to a pre-irradiation heat treatment (prebaking);
(4) irradiating a region to serve as the core or a region except the region to serve as the core in the above photosensitive resin composition layer with an active light beam such as an ultraviolet ray through a mask;
(5) subjecting the resultant to post-exposure heating (post-baking) to form a core layer; and
(6) forming an upper clad layer on the core layer and the lower clad layer thus formed.

In addition, at least one of the lower clad and the intermediate/upper clad described above may be formed of the photosensitive resin composition of this invention by irradiation with a chemical ray in the same manner as that described above; in this case, composition having a lower refractive index than that of the core layer is selected and used.

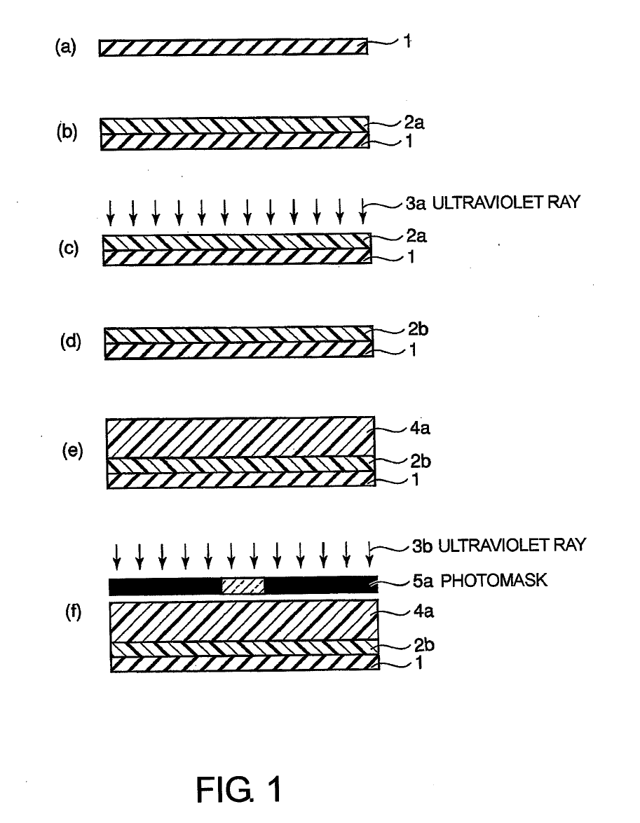

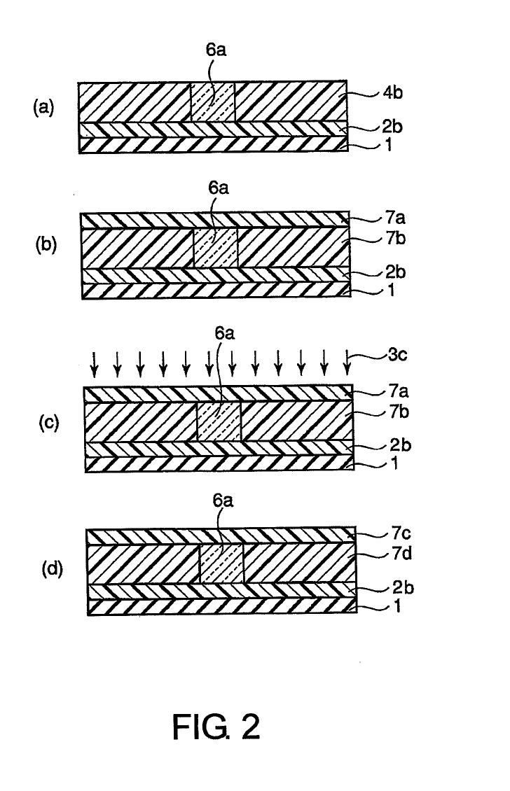

Hereinafter, an example of a method of producing the polymer optical waveguide according to this invention will be described in detail with reference to FIGS. 1 and 2.

First, as shown in FIG. 1(d), a lower clad layer (first clad layer) 2b is formed on an appropriate substrate 1. The lower clad layer 2b is formed by, for example, the following procedure. As shown in FIG. 1(b), a resin composition; including photosensitive resin composition 2a of this invention is applied onto the substrate 1 shown in FIG. 1(a), and the resultant is prebaked so that a layer of the above resin composition 2a is formed. Next, as shown in FIG. 1(c), the entire surface of the resin composition layer 2a is exposed to active light beams 3a, and the resultant is subjected to a heat treatment (baking) step so that the refractive index of the resin layer 2a may be reduced. Thus, the lower clad layer 2b is formed (FIG. 1(d)). The lower clad layer 2b may be obtained by using any other curable resin composition having a refractive index comparable to that of the resin composition through irradiation with active light beams or a heat treatment.

In this invention, for example, a silicon substrate, a glass substrate, a quartz substrate, a glass epoxy substrate, a metal substrate, a ceramic substrate, a polymer film, or a substrate obtained by forming a polymer film on any one of the various substrates can be used as the above substrate 1. However, the substrate is not limited to the foregoing.

Next, as shown in FIG. 1(e), the photosensitive resin composition of this invention is applied onto the above lower clad layer 2b, and the resultant is prebaked so that a photosensitive resin composition layer 4a is formed. Composition having a higher refractive index than that of the lower clad layer 2b is selected and used in the formation of the photosensitive resin composition layer 4a. A method of applying the photosensitive resin composition is not particularly limited, and, for example, spin coating with a spin coater, spray coating with a spray coater, dipping, printing, or roll coating can be employed. In addition, the prebaking step is a step intended for the following purpose: the applied resin composition including photosensitive resin composition is dried so that the solvent in the composition may be removed, and the applied resin composition is fixed as the resin composition layer 4a. The prebaking step is typically performed at 60 to 160° C.

Next, as shown in FIG. 1(f), a region corresponding to a core layer 6a of the above photosensitive resin composition layer 4a is irradiated with chemical rays 3b through a photomask 5a, and, furthermore, the resultant is subjected to a post-exposure heat treatment. Next, development is performed with an organic solvent so that an unexposed portion may be removed. After that, the remainder is further subjected to post-baking. Thus, as shown in FIG. 2(a), the core layer 6a having a higher refractive index is formed on the lower clad layer 2b.

The exposing step is a step of selectively exposing the photosensitive resin composition layer 4a to light through the photomask 5a to transfer a waveguide pattern on the photomask 5a onto the photosensitive resin composition layer 4a. Light beams from a high-pressure mercury lamp, light beams from a deuterium lamp, ultraviolet rays, visible rays, excimer laser, electron beams, X-rays, or the like can be used as the active light beams 3b used in the exposure of an entire surface described above and below, and in the pattern exposure; active light beams each having a wavelength of 180 to 500 nm are preferable.

In addition, the post-exposure heat treatment step is performed in air or under an inert gas atmosphere at 100 to 160° C. in ordinary cases.

In addition, the post-baking step is performed in air or under an inert gas atmosphere at 100 to 200° C. in ordinary cases. The post-baking step may be performed in one stage, or may be performed in multiple stages.

Further, a photosensitive resin composition 7a of this invention is applied onto the core layer 6a as shown in FIG. 2(b). Then, as shown in FIG. 2(c), the entire surface of the resin composition 7a is exposed to active light beams 3c, and the resultant is subjected to a heat treatment so that the refractive index of the resin composition 7a is reduced. Thus, as shown in FIG. 2(d), an intermediate clad and an upper clad (an intermediate clad layer 7d and an upper clad layer 7c: a second clad layer) are collectively formed. Each of the intermediate and upper clad layers 7d and 7c may be obtained by using any other photosensitive resin composition having a refractive index comparable to that of the resin composition through irradiation with ultraviolet rays or a heat treatment. Thus, a polymer optical waveguide of such a form that the core layer 6a having a higher refractive index is surrounded with the lower clad layer 2b, and the intermediate and upper clad layers 7d and 7c each having a lower refractive index can be produced. Further, after that, the substrate 1 is removed by a method such as etching, whereby a polymer optical waveguide can be obtained. In addition, when, for example, a flexible polymer film is adopted as the substrate 1, a flexible polymer optical waveguide can be obtained.

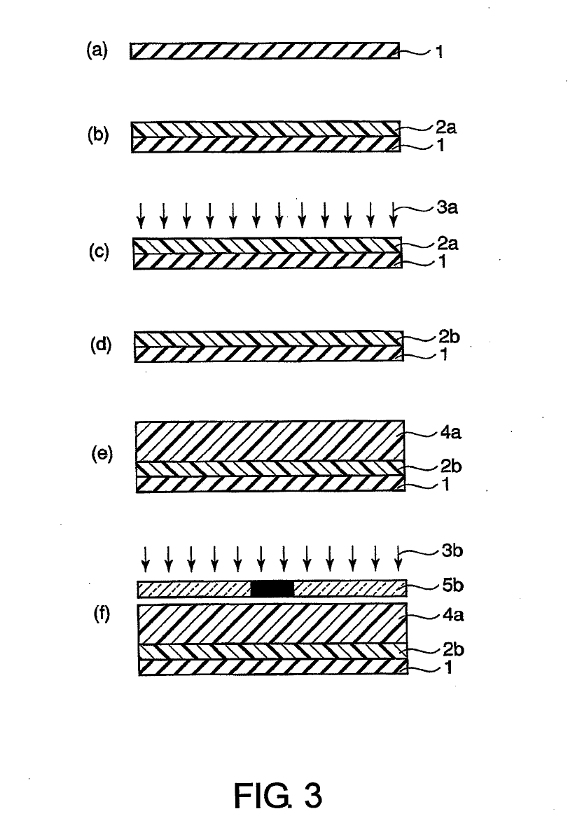

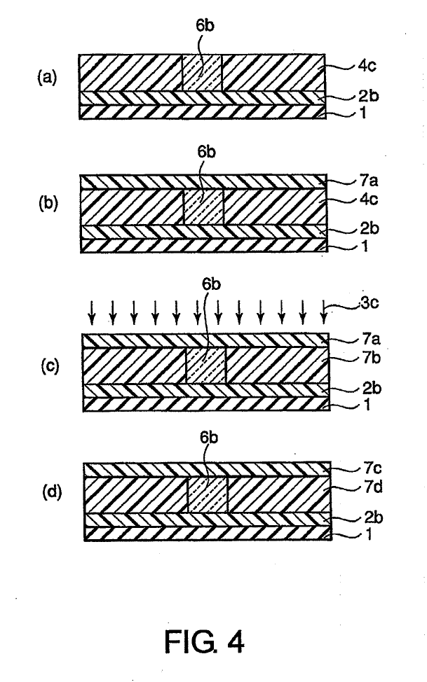

Next, another example of the method of producing the polymer optical waveguide according to this invention will be described in detail with reference to FIGS. 3 and 4.

First, as shown in FIG. 3(d), the lower clad layer (first clad layer) 2b is formed on the appropriate substrate 1. The lower clad layer 2b is formed by, for example, the following procedure. As shown in FIG. 3(b), the resin composition including photosensitive resin composition 2a of this invention is applied onto the substrate 1 shown in FIG. 3(a), and the resultant is prebaked so that a layer of the above resin composition 2a is formed. Next, as shown in FIG. 3(c), the entire surface of the resin composition layer 2a is exposed to the active light beams 3a, and the resultant is subjected to a heat treatment (baking) step so that the refractive index of the resin layer 2a is reduced. Thus, the lower clad layer 2b is formed (FIG. 3(d)). The lower clad layer 2b may be obtained by using any other curable resin composition having a refractive index comparable to that of the resin composition through irradiation with active light beams or a heat treatment.

In this invention, as in the case of the foregoing example, for example, a silicon substrate, a glass substrate, a quartz substrate, a glass epoxy substrate, a metal substrate, a ceramic substrate, a polymer film, or a substrate obtained by forming a polymer film on any one of the various substrates can be used as the above substrate 1. However, the substrate is not limited to the foregoing.

Next, as shown in FIG. 3(e), the photosensitive resin composition of this invention is applied onto the above lower clad layer 2b, and the resultant is prebaked so that the photosensitive resin composition layer 4a is formed. Composition having a higher refractive index than that of the lower clad layer 2b is selected and used in the formation of the photosensitive resin composition layer 4a. A method of applying the photosensitive resin composition is not particularly limited, and, for example, spin coating with a spin coater, spray coating with a spray coater, dipping, printing, or roll coating can be employed. In addition, the prebaking step is a step intended for the following purpose: the applied resin composition including photosensitive resin composition is dried so that the solvent in the composition may be removed, and the applied resin composition is fixed as the resin composition layer 4a. The prebaking step is typically performed at 60 to 160° C.

Next, as shown in FIG. 3(f), a region except the region corresponding to the core layer 6a of the above photosensitive resin composition layer 4a is irradiated with the chemical rays 3b through the photomask 5a, and, furthermore, the resultant is subjected to a post-exposure heat treatment. Next, development is performed with an organic solvent so that an unexposed portion is removed. After that, the remainder is further subjected to post-baking. Thus, as shown in FIG. 4(a), a core layer 6b having a higher refractive index is formed on the lower clad layer 2b.

The exposing step is a step of selectively exposing the photosensitive resin composition layer 4a to light through the photomask 5b to transfer the waveguide pattern on the photomask 5b onto the photosensitive resin composition layer 4a. Light beams from a high-pressure mercury lamp, light beams from a deuterium lamp, ultraviolet rays, visible rays, excimer laser, electron beams, X-rays, or the like can be used as the active light beams 3b used in the exposure of an entire surface described above and below, and in the pattern exposure; active light beams each having a wavelength of 180 to 500 nm are preferable.

In addition, the post-exposure heat treatment step is performed in air or under an inert gas atmosphere at 100 to 160° C. in ordinary cases.

In addition, the post-baking step is performed in air or under an inert gas atmosphere at 100 to 200° C. in ordinary cases. The post-baking step may be performed in one stage, or may be performed in multiple stages.

Further, the photosensitive resin composition 7a of this invention is applied onto the core layer 6b as shown in FIG. 4(b). Then, as shown in FIG. 4(c), the entire surface of the resin composition 7a is exposed to the active light beams 3c, and the resultant is subjected to a heat treatment so that the refractive index of the resin composition 7a is reduced. Thus, as shown in FIG. 4(d), an intermediate clad and an upper clad (the intermediate clad layer 7d and the upper clad layer 7c: the second clad layer) are collectively formed. Each of the intermediate and upper clad layers 7d and 7c may be obtained by using any other photosensitive resin composition having a refractive index comparable to that of the resin composition through irradiation with ultraviolet rays or a heat treatment. Thus, a polymer optical waveguide of such a form that the core layer 6b having a higher refractive index is surrounded with the lower clad layer 2b, and the intermediate and upper clad layers 7d and 7c each having a lower refractive index can be produced. Further, after that, the substrate 1 is removed by a method such as etching, whereby a polymer optical waveguide can be obtained. In addition, when, for example, a flexible polymer film is adopted as the substrate 1, a flexible polymer optical waveguide can be obtained.

(Mechanism Via which Difference in Refractive Index is Expressed by Exposure of Photosensitive Resin Composition to Light)

The reason why a difference in refractive index between an exposed portion and an unexposed portion is expressed by the exposure of the photosensitive resin composition to light in this invention will be described. A reaction occurring during post-baking in the exposed portion in this invention is represented by a reaction formula (1) shown below, and a reaction occurring during post-baking in the unexposed portion in this invention is represented by a reaction formula (2) shown below. In the exposed portion, an acid is released from the photo-acid-generating agent by UV light, and the acid diffuses in the photosensitive resin. The acid promotes the hydrolysis reaction of each of the side chain portions R3 and R4 of the polyamic acid. A carboxyl group produced by the hydrolysis undergoes an intermolecular reaction with an epoxy group, whereby a covalent bond is formed between the polyamic acid side chain and the epoxy group. A novel structure produced by the intermolecular reaction does not undergo dehydration ring closure/imidation at the dehydration ring closure (thermal imidation) temperature of an amic acid (typically 200° C. or lower). On the other hand, in the unexposed portion, first, an amic acid portion of the polyamic acid undergoes dehydration ring closure at 200° C. or lower, whereby an ordinary thermal imidation reaction proceeds. In addition, most of the epoxy compound in the unexposed portion react with each other at their epoxy groups to form a crosslinked structure, but part of the epoxy compound decompose or evaporate to be discharged to the outside of the system. As a result, the imidation ratio of the exposed portion is much lower than that of the unexposed portion; this is mainly responsible for the expression of the difference in refractive index.

(A) A reaction occurring after the post-curing of the exposed portion (an intermolecular reaction between an amic acid and an epoxy group: thermal imidation of the resultant is hard, and an increase in refractive index of the exposed portion is small.)

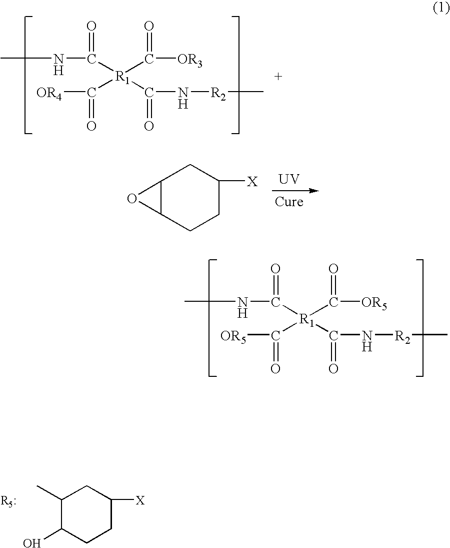

(B) A reaction occurring after the post-curing of the unexposed portion (an ordinary thermal imidation reaction proceeds, and the refractive index of the unexposed portion significantly increases. Most of the epoxy compound react with each other at their epoxy groups to form a crosslinked structure, but part of the epoxy compound decompose or evaporate to be discharged to the outside of the system.)

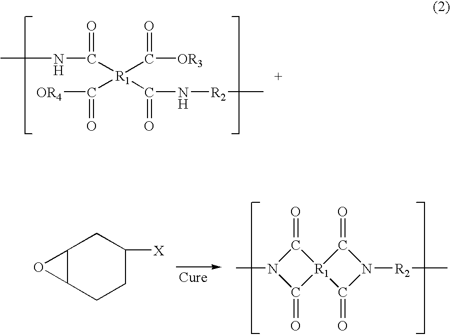

### EXAMPLES

Hereinafter, this invention will be described more specifically by way of examples.

### Example 1

First, 7.77 (g) of 4,4′-diaminodiphenyl ether (ODA) were dissolved in 100 (g) of dimethylacetamide, and the solution was stirred well at room temperature. After that, 10.48 (g) of N,O-bis(trimethylsilyl)-trifluoroacetamide (BSTFA) were added to the solution, and the mixture was stirred under a nitrogen atmosphere at room temperature for 30 minutes. After that, 17.23 (g) of 4,4′-hexafluoroisopropylidenediphthalic dianhydride (6FDA) were added to the mixture, and the whole was stirred under a nitrogen atmosphere at room temperature for one day, whereby a polyamic acid solution (1) having a solute concentration of 20 wt % was synthesized.

The 20-wt % polyamic acid solution (1) thus obtained, 3,4-epoxycyclohexanecarboxylic acid-3′,4′-epoxycyclohexylmethyl as an epoxy compound, and a photo-acid-generating agent 4-thiophenoxyphenyldiphenylsulfonium hexafluoroantimonate were mixed according to the composition shown in Table 1, and the mixture was stirred at room temperature for 2 hours, whereby a mixed solution was obtained.

The above mixture was filtrated with a 0.45-μm filter made of Teflon (registered trademark), whereby a photosensitive resin composition was prepared. The above photosensitive resin was applied onto a silicon substrate having a diameter of 4 inches by spin coating, and the resultant was subjected to a heat treatment at 70° C. for 20 minutes, whereby a coating film was formed. Next, the entire surface of the coating film was exposed to ultraviolet light (at an exposure value of 1 J/cm²) from a high-pressure mercury lamp (250 W). After that, an exposed sample and an unexposed sample were each subjected to a heat treatment in a stream of nitrogen at 120° C. for 20 minutes. After that, each of the samples was further thermally imidated at each of 150° C. and 210° C. for 1 hour. The refractive index of each of the exposed sample and the unexposed sample thus obtained at a wavelength of 1,320 nm was measured with a Prism Coupler PC-2000 manufactured by Metricon Corporation. Table 1 below shows the results of the measurement.

TABLE 1

| | Composition 1 | Composition 2 | Composition 3 | Composition 4 |
|---|---|---|---|---|
| Polyamic acid (g) | 6 | 6 | 6 | 6 |
| Epoxy compound (g) | 9 | 6 | 5 | 4 |
| Photo-acid-generating | 0.45 | 0.3 | 0.25 | 0.2 |
| agent (g) | | | | |
| Refractive index | 1.5439 | 1.5448 | 1.5347 | 1.5408 |
| (Exposed portion) | | | | |
| Refractive index | 1.5500 | 1.5486 | 1.5446 | 1.5487 |
| (Unexposed portion) | | | | |
| Percentage by which | 0.40 | 0.25 | 0.65 | 0.51 |
| refractive index | | | | |
| changed (%) | | | | |

The light transmittance of a film formed of the mixed liquid having the composition 4 under conditions identical to those described above was measured with an automatic spectrophotometer. As a result, the film showed a high transmittance of 85% or more in a visible to near-infrared region.

### Example 2

8.76 (g) of bis(4-aminocyclohexyl)methane (DCHM) were loaded into 100 (g) of γ-butyrolactone, and the mixture was stirred well at room temperature. After that, 20.74 (g) of N,O-bis(trimethylsilyl)-trifluoroacetamide (BSTFA) were added to the mixture, and the whole was stirred under a nitrogen atmosphere at room temperature for 30 minutes. After that, 34.09 (g) of 4,4′-hexafluoroisopropylidenediphthalic dianhydride (6FDA) were added to the resultant, and the mixture was stirred under a nitrogen atmosphere at room temperature for one day, whereby a polyamic acid solution (2) having a solute concentration of 30 wt % was synthesized. The 30-wt % polyamic acid solution (2) thus obtained, an epoxy compound, and a photo-acid-generating agent 4-thiophenoxyphenyldiphenylsulfonium hexafluoroantimonate were mixed according to the composition shown in Table 2, and the mixture was stirred at room temperature for 2 hours, whereby a mixed solution was obtained.

The above mixture was filtrated with a 0.45-μm filter made of Teflon (registered trademark), whereby a photosensitive resin composition was prepared. The above photosensitive resin composition was applied onto a silicon substrate having a diameter of 4 inches by spin coating, and the resultant was subjected to a heat treatment at 70° C. for 20 minutes, whereby a coating film was formed. Next, the entire surface of the coating film was exposed to ultraviolet light (at an exposure value of 1 J/cm²) from a high-pressure mercury lamp (250 W). After that, an exposed sample and an unexposed sample were each subjected to a heat treatment in a stream of nitrogen at 120° C. for 20 minutes. After that, each of the samples was further thermally imidated at each of 150° C. and 200° C. for 1 hour. The refractive index of each of the exposed sample and the unexposed sample thus obtained at a wavelength of 1,320 nm was measured with a Prism Coupler manufactured by Metricon Corporation. Table 2 below shows the results of the measurement.

TABLE 2

| | Composition 1 | Composition 2 | Composition 3 | Composition 4 |
|---|---|---|---|---|
| Polyamic acid (g) | 6 | 6 | 6 | 6 |
| Epoxy compound (g) | 12 | 9 | 6 | 4 |
| Photo-acid-generating | 0.6 | 0.45 | 0.3 | 0.2 |
| agent (g) | | | | |
| Refractive index | 1.5071 | 1.5059 | 1.5063 | 1.5071 |
| (Exposed portion) | | | | |
| Refractive index | 1.5115 | 1.5100 | 1.5081 | 1.5154 |
| (Unexposed portion) | | | | |
| Percentage by which | 0.29 | 0.27 | 0.12 | 0.55 |
| refractive index | | | | |
| changed (%) | | | | |

The light transmittance of a film formed of the mixed liquid having the composition 4 under conditions identical to those described above was measured with an automatic spectrophotometer. As a result, the film showed a high transmittance of 80% or more in a visible to near-infrared region. The glass transition temperature of the resultant film was measured with an apparatus for thermomechanical analysis (TMA). As a result, the glass transition temperature was 200° C. The thermal decomposition-starting temperature of the film was measured with an apparatus for thermogravimetry (DTG-60 manufactured by Shimadzu Corporation). As a result, the film started to decompose thermally at about 230° C. A 5% weight reduction temperature (T_{d}⁵) of the film was 275° C., which meant that the film had high heat resistance.

### Example 3

The mixed liquid having the composition 4 shown in Example 2 was filtrated with a 0.45-μm filter made of Teflon (registered trademark), whereby a photosensitive resin composition for the production of a waveguide was prepared. Next, the above photosensitive resin for the formation of the clad was applied onto a silicon substrate having a diameter of 4 inches by spin coating, and the resultant was subjected to a heat treatment at 70° C. for 20 minutes, whereby a coating film having a thickness of 10 μm was formed. Next, the entire surface of the coating film was exposed to ultraviolet light (at an exposure value of 1 J/cm²) from a high-pressure mercury lamp (250 W). After the exposure, the resultant was subjected to a heat treatment in a stream of nitrogen at 120° C. for 20 minutes, and, furthermore, was thermally imidated at each of 150° C. and 200° C. for 1 hour, whereby a lower clad layer was formed. Next, the above photosensitive resin was applied onto the lower clad layer by spin coating, and the resultant was subjected to a heat treatment at 70° C. for 20 minutes, whereby a coating film having a thickness of 20 μm was formed. Next, the resultant was irradiated with ultraviolet rays at 1 J/cm² from a high-pressure mercury lamp (250 W) through a photomask. Next, the resultant was subjected to a heat treatment in a stream of nitrogen at 120° C. for 20 minutes. Next, the resultant was subjected to a curing treatment at each of 150° C. and 200° C. for 1 hour, whereby a core layer pattern was formed. Next, the above photosensitive resin was applied onto the core layer pattern by spin coating, and the resultant was subjected to a heat treatment at 70° C. for 20 minutes, whereby a film having a thickness of 10 μm was formed. Next, the entire surface of the film was exposed to ultraviolet light (at an exposure value of 1 J/cm²) from a high-pressure mercury lamp (250 W). After the exposure, the resultant was subjected to a heat treatment in a stream of nitrogen at 120° C. for 20 minutes, and, furthermore, was thermally imidated at each of 150° C. and 200° C. for 1 hour, whereby an upper clad layer was formed. Thus, a polymer optical waveguide was obtained. The resultant waveguide was peeled from the substrate. As a result, the waveguide had good film quality and high flexibility.

### INDUSTRIAL APPLICABILITY

As is apparent from the foregoing description, the use of the photosensitive resin composition for the formation of a polymer optical waveguide of this invention enables the formation of a waveguide pattern with high accuracy, and the formed optical waveguide shows an excellent transmission characteristic, i.e., low propagation loss. Accordingly, the photosensitive resin composition is suitable as a material for the formation of an optical waveguide.

This application claims a priority based on Japanese Patent Application No. 2006-238847 filed on Sep. 4, 2006, all the contents of which are incorporated herein.

1. A photosensitive resin composition, comprising:
a polyamic acid (A) represented by a general formula (I); a compound (B) having an epoxy group; and
a compound (C) which generates an acid by being exposed to light: 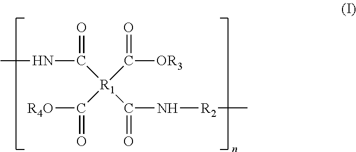
where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

2. A photosensitive resin composition according to claim 1, wherein R1 represents at least one kind of a tetravalent organic functional group selected from the group consisting of:
a tetravalent functional group containing at least one of organic benzene, a monoalkylbenzene, and a monoperfluoroalkylbenzene;
a tetravalent functional group containing at least one of an aromatic hydrocarbon having two or more benzene rings, an ether of the aromatic hydrocarbon, a ketone of the aromatic hydrocarbon, a substituted body of the aromatic hydrocarbon with one or more perfluoroalkyl groups; and tetravalent organic functional groups having a structure obtained by replacing part or all of carbons in aromatic rings of the aromatic hydrocarbon with saturated carbons each of which is free of aromaticity by an approach such as a hydrogenation treatment.

3. A photosensitive resin composition according to claim 1, wherein R2 represents a residue obtained by removing amino groups of a diamine compound capable of reacting with one of a tetracarboxylic acid and a derivative of the tetracarboxylic acid to form a polyimide precursor.

4. A photosensitive resin composition according to claim 3, wherein R2 represents at least one kind of
a phenylene group, a perfluoroalkylphenylene group, a fluorophenylene group, and an alkylphenylene group each having one benzene ring,
a divalent organic functional group having two or more benzene rings, a divalent organic functional group containing Si, and
a divalent organic functional group having a structure obtained by replacing part or all of carbons in an aromatic ring of each of the groups with saturated carbons each of which is free of aromaticity by an approach such as a hydrogenation treatment.

5. A photosensitive resin composition according to claim 4, wherein R2 is a divalent organic functional group having one benzene ring, and is free from an alkylphenylene group and a perfluorophenylene group.

6. A photosensitive resin composition according to claim 1, wherein the photosensitive resin composition contains the polyamic acid (A) at a content of 5 to 90 mass %, the compound (B) at a content of 0.5 to 80 mass %, and the compound (C) at a content of 0.5 to 15 mass %.

7. A photosensitive resin composition according to claim 1, further comprising an oxetane compound.

8. A photosensitive resin composition according to claim 1, further comprising at least one additive selected from the group consisting of alumina, silica, a glass fiber, a glass bead, silicone, titanium oxide, and a metal oxide.

9. A photosensitive resin composition according to claim 1, wherein, when the photosensitive resin composition is irradiated with an active light beam and is subsequently heated, a difference in refractive index arises between an exposed portion and an unexposed portion.

10. A method of controlling a refractive index, comprising: irradiating a photosensitive resin composition with an active light beam; and
subsequently heating the photosensitive resin composition to cause a difference in refractive index to arise between a portion exposed to the active light beam and a portion unexposed to the active light beam,
wherein the photosensitive resin composition contains a polyamic acid
represented by a general formula (I) shown below, a compound
having an epoxy group, and a compound (C) which generates an acid by being exposed to light: 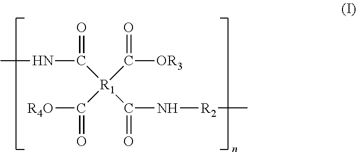
where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen or a functional group which decomposes with an acid.

11. A method of controlling a refractive index according to claim 10, wherein R1 in the photosensitive resin composition represents at least one kind of a tetravalent organic functional group selected from the group consisting of: a tetravalent organic functional group containing at least one of benzene, a monoalkylbenzene, and a monoperfluoroalkylbenzene;
a tetravalent organic functional group containing at least one of an aromatic hydrocarbon having two or more benzene rings, an ether of the aromatic hydrocarbon, a ketone of the aromatic hydrocarbon, a substituted body of the aromatic hydrocarbon with one or more perfluoroalkyl groups; and tetravalent organic functional groups having a structure obtained by replacing part or all of carbons in aromatic rings of the aromatic hydrocarbon with saturated carbons each of which is free of aromaticity by an approach such as a hydrogenation treatment.

12. A method of controlling a refractive index according to claim 10, wherein R2 represents a residue obtained by removing amino groups of a diamine compound capable of reacting with one of a tetracarboxylic acid and a derivative of the tetracarboxylic acid to form a polyimide precursor.

13. A method of controlling a refractive index according to claim 12, wherein R2 represents at least one kind of a phenylene group, a perfluoroalkylphenylene group, a fluorophenylene group, and an alkylphenylene group each having one benzene ring,
a divalent organic functional group having two or more benzene rings, a divalent organic functional group containing Si, and
a divalent organic functional group having a structure obtained by replacing part or all of carbons in an aromatic ring of each of the groups with saturated carbons each of which is free of aromaticity by an approach such as a hydrogenation treatment.

14. A method of controlling a refractive index according to claim 13, wherein R2 is a divalent organic functional group having one benzene ring, and is free from an alkylphenylene group and a perfluorophenylene group.

15. A method of controlling a refractive index according to claim 10, wherein the photosensitive resin composition contains the polyamic acid (A) at a content of 5 to 90 mass %, the compound (B) at a content of 0.5 to 80 mass %, and the compound (C) at a content of 0.5 to 15 mass %.

16. A method of controlling a refractive index according to claim 10, wherein the photosensitive resin composition further comprises an oxetane compound.

17. A method of controlling a refractive index according to claim 10, wherein the photosensitive resin composition further comprises at least one additive selected from the group consisting of alumina, silica, a glass fiber, a glass bead, silicone, titanium oxide, and a metal oxide.

18. A method of controlling a refractive index according to claim 10, wherein, by irradiating the active light beam and subsequently heating, a difference in refractive index arises between an exposed portion and an unexposed portion.

19. An optical waveguide, wherein a portion having a higher refractive index and a portion having a lower refractive index, which are obtained by the method of controlling a refractive index according to claim 18, are used as a core and a clad, respectively.

20. An optical waveguide, comprising:
a core layer; and
a clad layer formed by lamination on the core layer,
wherein a photosensitive resin composition is used in one or both of the core layer and the clad layer, and the photosensitive resin composition contains a polyamic acid (A) represented by a general formula (I) shown below, a compound (B) having an epoxy group, and a compound (C) which generates an acid by being exposed to light: 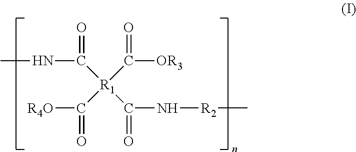
where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

21. An optical waveguide according to claim 20, wherein R1 represents at least one kind of a tetravalent organic functional group selected from the group consisting of:
a tetravalent organic functional group containing at least one of benzene, a monoalkylbenzene, and a monoperfluoroalkylbenzene;
a tetravalent organic functional group containing at least one of an aromatic hydrocarbon having two or more benzene rings, an ether of the aromatic hydrocarbon, a ketone of the aromatic hydrocarbon, a substituted body of the aromatic hydrocarbon with one or more perfluoroalkyl groups; and tetravalent organic functional groups having a structure obtained by replacing part or all of carbons in aromatic rings of the aromatic hydrocarbon with saturated carbons each of which is free of aromaticity by an approach such as a hydrogenation treatment.

22. An optical waveguide according to claim 21, wherein R2 represents a residue obtained by removing amino groups of a diamine compound capable of reacting with one of a tetracarboxylic acid and a derivative of the tetracarboxylic acid to form a polyimide precursor.

23. An optical waveguide according to claim 22, wherein R2 represents at least one kind of
a phenylene group, a perfluoroalkylphenylene group, a fluorophenylene group, and an alkylphenylene group each having one benzene ring,
a divalent organic functional group having two or more benzene rings, a divalent organic functional group containing Si, and
a divalent organic functional group having a structure obtained by replacing part or all of carbons in an aromatic ring of each of the groups with saturated carbons each of which is free of aromaticity by an approach such as a hydrogenation treatment.

24. An optical waveguide according to claim 23, wherein R2 is a divalent organic functional group having one benzene ring, and is free from an alkylphenylene group and a perfluorophenylene group.

25. An optical waveguide according to claim 20, wherein the photosensitive resin composition contains the polyamic acid (A) at a content of 5 to 90 mass %, the compound (B) at a content of 0.5 to 80 mass %, and the compound (C) at a content of 0.5 to 15 mass %.

26. An optical waveguide according to claim 20, wherein the photosensitive resin composition further comprises an oxetane compound.

27. An optical waveguide according to claim 20, wherein the photosensitive resin composition further comprises at least one additive selected from the group consisting of alumina, silica, a glass fiber, a glass bead, silicone, titanium oxide, and a metal oxide.

28. An optical waveguide according to claim 20, wherein, when the photosensitive resin composition is irradiated with an active light beam and subsequently heated, a difference in refractive index arises between an exposed portion and an unexposed portion.

29. An optical waveguide according to claim 28, wherein, out of the exposed portion and the unexposed portion, a portion having a higher refractive index is used as a core, and a portion having a lower refractive index is used as a clad.

30. A method of forming an optical waveguide pattern, comprising at least the steps of:
forming a first clad layer on a substrate;
applying a photosensitive resin composition onto the first clad layer; prebaking the resultant;
irradiating one of a region to serve as a core and a region to serve as a portion except the core in the photosensitive resin composition layer with an active light beam through a mask; and
forming a second clad layer on the core and the first clad layer thus formed,
wherein the photosensitive resin composition contains a polyamic acid
represented by a general formula (I) shown below, a compound
having an epoxy group, and a compound (C) which generates an acid by being exposed to light: 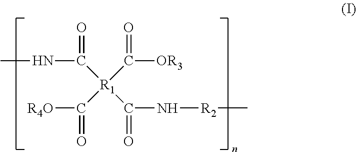
where R1 represents a tetravalent organic functional group except tetravalent organic functional groups of a bisalkylbenzene and a bisperfluoroalkylbenzene, R2 represents a divalent organic functional group, and R3 and R4 each independently represent a hydrogen atom or a functional group which decomposes with an acid.

31. A method of forming an optical waveguide pattern according to claim 30, wherein R1 represents at least one kind of a tetravalent organic functional group selected from the group consisting of:
a tetravalent organic functional group containing at least one of benzene, a monoalkylbenzene, and a monoperfluoroalkylbenzene;
a tetravalent organic functional group containing an aromatic hydrocarbon having two or more benzene rings, an ether of the aromatic hydrocarbon, a ketone of the aromatic hydrocarbon, a substituted body of the aromatic hydrocarbon with one or more perfluoroalkyl groups; and
tetravalent organic functional groups having a structure obtained by replacing part or all of carbons in aromatic rings of the aromatic hydrocarbon with saturated carbons each of which is free of aromaticity by an approach such as a hydrogenation treatment.

32. A method of forming an optical waveguide pattern according to claim 30, wherein R2 represents a residue obtained by removing amino groups of a diamine compound capable of reacting with one of a tetracarboxylic acid and a derivative of the acid to form a polyimide precursor.

33. A method of forming an optical waveguide pattern according to claim 32, wherein R2 represents at least one kind of
a phenylene group, a perfluoroalkylphenylene group, a fluorophenylene group, and an alkylphenylene group each having one benzene ring,
a divalent organic functional group having two or more benzene rings, a divalent organic functional group containing Si, and
a divalent organic functional group having a structure obtained by replacing part or all of carbons in an aromatic ring of each of the groups with saturated carbons each of which is free of aromaticity by an approach such as a hydrogenation treatment.

34. A method of forming an optical waveguide pattern according to claim 33, wherein R2 is a divalent organic functional group having one benzene ring, and is free from an alkylphenylene group and a perfluorophenylene group.

35. A method of forming an optical waveguide pattern according to claim 30, wherein the photosensitive resin composition contains the polyamic acid (A) at a content of 5 to 90 mass %, the compound (B) at a content of 0.5 to 80 mass %, and the compound (C) at a content of 0.5 to 15 mass %.

36. A method of forming an optical waveguide pattern according to claim 30, wherein the photosensitive resin composition further comprises an oxetane compound.

37. A method of forming an optical waveguide pattern according to claim 30, wherein the photosensitive resin composition further comprises at least one additive selected from the group consisting of alumina, silica, a glass fiber, a glass bead, silicone, titanium oxide, and a metal oxide.

38. A method of forming an optical waveguide pattern according to claim 30, wherein, by irradiating the active light beam and subsequently heating, a difference in refractive index arises between an exposed portion and an unexposed portion.

39. A method of forming an optical waveguide pattern according to claim 38, wherein a layer is formed of the photosensitive resin composition as a starting material by application on the first clad layer in such a manner that a portion of the layer irradiated with the active light beam after the formation has a lower refractive index than a refractive index of a portion except the irradiated portion.

40. A method of forming an optical waveguide pattern according to claim 38, wherein a layer is formed of the photosensitive resin composition as a starting material by application on the first clad layer in such a manner that a portion of the layer irradiated with the active light beam after the formation has a higher refractive index than a refractive index of a portion except the irradiated portion.

41. An optical component comprising an optical element or device, wherein the optical component uses an optical waveguide formed by the method of forming a waveguide pattern according to claim 30.
